(19) United States
(12) Patent Application Publication
(10) Pub. No.: US 2009/0321111 A1
(43) Pub. Date: Dec. 31, 2009

(54) FLEXIBLE PRINTED CIRCUIT MODULE

(75) Inventor: CHUN-HUA WU, Tu-Cheng City (TW)

Correspondence Address: PCE INDUSTRY, INC.;ATT. Steven Reiss, 288 SOUTH MAYO AVENUE, CITY OF INDUSTRY, CA, 91789, US

(73) Assignee: Chi Mei Communication Systems, Inc., Tu-Cheng City (TW)

(21) Appl. No.: 12/396,544

(22) Filed: Mar. 3, 2009

(30) Foreign Application Priority Data
Jun. 27, 2008 (CN) 200810302390.2

(51) Int. Cl. H05K 1/00

(52) U.S. Cl. 174/254

(57) ABSTRACT

A flexible printed circuit module includes a main body and at least one connecting socket. The main body includes a first connecting end, a strip body and a second connecting end. The first connecting end and the second connecting end each includes a connector, disposed thereon respectively. The strip body includes a plurality of internal circuits including a grounding circuit assembled therein, the internal circuits electronically connect with the two connectors. The connecting socket is mounted on the main body and electronically connects with one of the two connectors and has a conductive coating covered on an area of the main body surrounding the connecting socket electronically connecting with the grounding circuit.

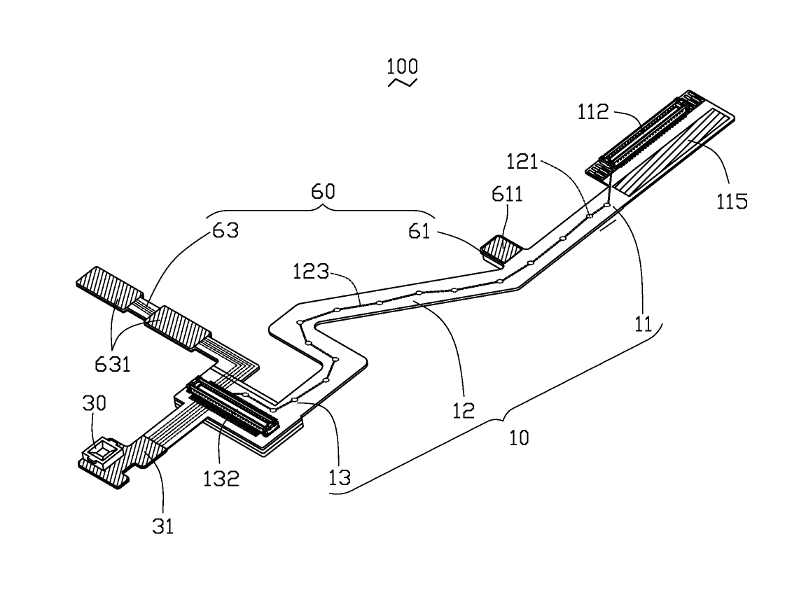

### BACKGROUND

1. Technical Field

The present invention relates to a flexible printed circuit module, particularly to a flexible printed circuit module configured for increasing the grounding contact area.

2. Discussion of the Related Art

Because of their light weight, thinness and easy ability to be bent multiple times, flexible printed circuit modules are widely used within portable electronic devices such as mobile phones and personal digital assistants (PDAs), etc.

When used, the electronic components and circuits assembled within an electronic device can generate electrostatic charges. If these electrostatic charges cannot be effectively released to ground, electrostatic discharge (ESD) might occur among the electronic components and circuits to influence the normal work and performance of the portable electronic device and thus damage the electronic device. To avoid the above-described damage to the electronic device, a grounding device is provided and electrically connected to the electronic components and the circuits to the grounding device by a flexible printed circuit to timely release the electrostatic charges of the electronic components and the circuits to ground by the grounding device to prevent the damage to the portable electronic device.

However, limited by the dimensions of conventional flexible printed circuits, the connectors at the two ends of the flexible printed circuit are not able to provide more grounding pins or more grounding areas. Therefore, the conventional flexible printed circuit can not provide enough grounding contacts to release the electrostatic charges generated by the electronic components.

Therefore, there is room for improvement within the art.

### BRIEF DESCRIPTION OF THE DRAWING

Many aspects of the present flexible printed circuit module can be better understood with reference to the drawing. The components in the drawings are not necessarily drawn to scale, the emphasis instead being placed upon clearly illustrating the principles of the present flexible printed circuit module.

The drawing shows a schematic view of the flexible printed circuit module, according to an exemplary embodiment of the present invention.

### DETAILED DESCRIPTION OF THE EMBODIMENT

Referring to the drawing, a schematic view of a flexible printed circuit module 100, according to an exemplary embodiment is shown. The flexible printed circuit module 100 includes a main body 10, at least one connecting socket 30 and at least one grounding strap 60. The main body 10 is a conventional flexible printed circuit, and includes a first connecting end 11, a strip body 12 and a second connecting end 13 opposite to the first connecting end 11. The first connecting end 11 has a first connector 112 disposed thereon. The second connecting end 13 has a second connector 132 disposed thereon. The strip body 12 defines a plurality of via holes 121, and has a plurality of internal circuits 123, including grounding circuits, disposed therein. The internal circuits 123 electrically connect with the first connector 112 and the second connector 132. In the present embodiment, the first connecting end 11 is coated or covered with a layer of conductive coating 115 on a surface, adjacent to the first connector 112. The conductive coating 115 can be a silver coating that connects with the grounding circuits within the strip body 12 by the via holes 121.

The connecting socket 30 is mounted on the main body 10, and electrically connects with the first connector 112 or the second connector 132 by the internal circuits 123 to electrically connect electric component(s) mounted thereon with the electric components connecting with the first and/or second connector 112, 132. The connecting socket 30 includes a grounding pin (not shown). In the present embodiment, the connecting socket 30 is mounted on one end of the main body 10 near the second connector 132 and configured for mounting a camera module thereon. A conductive coating 31 is coated/covered on a surface of the main body 10 near the second connector 132, surrounding the connecting socket 30. The conductive coating 31 electronically connects with the grounding pin of the connecting socket 30 and the grounding circuit of internal circuit 123. The conductive coating 31 can be a silver coating.

The grounding strap 60 is bar shaped and extends outwards from the strip body 12 of the main body 10 and electronically connects with grounding circuit of the internal circuits 123, to provide an enlarged grounding contact area for the flexible printed circuit module 100. In the present embodiment, the grounding strap 60 includes a first grounding strap 61 and a second ground strap 63. The first grounding strap 61 is disposed near the first connecting end 11 of the strip body 12 and extends outwards therefrom. The surface of the first grounding strap 61 is coated/covered with a conductive coating 611 thereon. The second grounding strap 63 is disposed near the second connecting end 13 of the strip body 12 and extends outwards therefrom. The area of the second grounding strap 63 can be larger than that of the first grounding strap 61. The surfaces of the second grounding strap 63 are coated/covered with a conductive coating 631 thereon. The conductive coatings 611, 613 electrically connect with the grounding portion of the portable electronic device so as to allow the release the electrostatic charges generating by the electric components of the portable electronic device. The conductive coatings 611, 631 can be a silver coating.

It is to be understood that, the grounding strap 60 could extends outwards from the strip body 12 with a plurality of flexible grounding straps.

It is to be understood, however, that even though numerous characteristics and advantages of the present invention have been set forth in the foregoing description, together with details of the structure and function of the present invention, the disclosure is illustrative only, and changes may be made in detail, especially in matters of shape, size, and arrangement of parts within the principles of present invention to the full extent indicated by the broad general meaning of the terms in which the appended claims are expressed.

What is claimed is:

1. A flexible printed circuit module, comprising:
a main body comprising:
a first connecting end having a first connector thereon;
a strip body comprising a plurality of internal circuits, including a grounding circuit assembled therein, the internal circuits electrically connecting with the first connector; and
a second connecting end having a second connector thereon for electrically connecting with the first connector via the internal circuits;
a connecting socket mounted on the main body, and electronically connecting with one of the first connector and the second connector, the connecting socket including a grounding pin; and
a conductive coating covered on an area of the main body, surrounding the connecting socket, the conductive coating electrically connecting with the grounding pin and the grounding circuit.

2. The flexible printed circuit module as claimed in claim 1, wherein the strip body further comprises a plurality of via holes defined therethrough, the first connecting end is covered with a layer of conductive coating on a surface adjacent to the first connector for electronically connecting with the grounding circuit within the strip body by the via holes.

3. The flexible printed circuit module as claimed in claim 2 further comprising at least one grounding strap extending outwards from the strip body and electronically connects with the grounding circuit, to provide an enlarged grounding contact area for the flexible printed circuit module.

4. The flexible printed circuit module as claimed in claim 3, wherein the grounding strap comprises a first grounding strap disposed near the first connecting end of the strip body.

5. The flexible printed circuit module as claimed in claim 4, wherein the surface of the first grounding strap is covered with a conductive coating and configured to electrically connect with the grounding portion of a portable electronic device to release the electrostatic charges.

6. The flexible printed circuit module as claimed in claim 5, wherein the grounding strap further comprises a second grounding strap disposed near the second connecting end of the strip body.

7. The flexible printed circuit module as claimed in claim 6, wherein the surface area of the second grounding strap is larger than the surface area of the first grounding strap.

8. The flexible printed circuit module as claimed in claim 7, the surface of the second grounding strap covered with a conductive coating and configured to electrically connect with the grounding portion of a portable electronic device to release the electrostatic charges.

9. The flexible printed circuit module as claimed in claim 8, wherein the conductive coating is a silver coating.

10. The flexible printed circuit module as claimed in claim 2, wherein the grounding strap extends from the strip body and comprises a plurality of flexible grounding straps.
